(19) United States
(12) Patent Application Publication
(10) Pub. No.: US 2026/0269565 A1
(43) Pub. Date: Sep. 10, 2026

(54) EDGE EMITTING LASER SYSTEM

(71) Applicant: VECTOR PHOTONICS LIMITED, Glasgow (GB)

(72) Inventors: Richard TAYLOR, Glasgow (GB); Calum HILL, Howwood (GB)

(21) Appl. No.: 19/162,646

(22) PCT Filed: Feb. 29, 2024
(86) PCT No.: PCT/GB2024/050550

§ 371 Date: Sep. 5, 2025

(30) Foreign Application Priority Data
Mar. 8, 2023 (GB) 2303401.0

(51) Int. Cl. H01S 5/11; H01S 5/40

(52) U.S. Cl. CPC H01S 5/11; H01S 5/4031

(57) ABSTRACT

An edge emitting laser (EEL) system and a method for manufacturing is disclosed. The EEL system comprises an EEL structure, configured to generate laser radiation along a first longitudinal axis defined by an active layer of the EEL system. The EEL system further comprises a photonic crystal structure. The photonic crystal structure is defined by a two-dimensional period array distributed in an array plane and is arranged to couple the generated laser radiation laterally across the EEL system. The presence of the photonic crystal structure within the EEL system results in light scattering orthogonally within the photonic crystal to the output field generated by the EEL system. The described EEL system allows for the area of the EEL system to be increased while maintaining a single spatial and longitudinal mode of operation, resulting in a coherent beam with a high output power.

The present invention relates to the field of semiconductor laser devices. In particular, the present invention relates to edge emitting laser (EEL) systems and methods for manufacturing the same.

Semiconductor laser devices are solid-state lasers based on semiconductor gain media, where optical amplification is usually achieved through stimulated recombination of charge carriers. Most semiconductor laser devices are laser diodes based on a semiconductor gain medium, which is pumped with an electrical current in a region where n-doped and p-doped semiconductor materials meet. As the photon energy of a laser diode is close to the bandgap energy, compositions with different bandgap energies allow for different emission wavelengths.

There is a great variety of semiconductor laser devices, spanning wide parameter regions and many different application areas. Edge emitting laser (EEL) devices are one class of semiconductor laser device. Edge emitting lasers are the original semiconductor laser device technology and have been in use for several decades. In an EEL the laser feedback and emission are both in-plane, so light comes out of an end of the laser and the gain reflection is produced by facet mirrors located at opposite ends of the laser. Edge emitting lasers can be operated in either a continuous-wave or pulsed mode.

As will be appreciated by the skilled reader, EEL devices can include, but are not limited to, Fabry Perot lasers (FP), distributed-feedback lasers (DFB lasers) and distributed Bragg reflector lasers (DBR lasers). In all of these devices, the laser feedback and emission are both in-plane. A Fabry Perot (FP) laser provides optical feedback by facet mirrors at each end of the laser. In contrast, both the DBR and DFB lasers contain a grating structure within the laser device to provide the optical feedback and to deliver a single-mode output beam. In a DFB laser the grating structure is along the active region, whereas a DBR laser places the grating structure outside of the active region.

EEL devices which simultaneously achieve high output powers and single-mode operation, along with a relatively small footprint are desirable for many commercial laser applications.

Higher operating powers can be obtained from EELs by simply increasing the area of the laser structure, as larger devices will generally emit more power. However, when increasing the width of the EEL, the high power comes at the expense of losing spatial coherence due to the device exhibiting the detrimental effects of spatial mode hopping. Similarly, increasing the length of the EEL device results in the laser lasing at additional longitudinal modes. As a result, broad area EELs are limited to applications where multi-mode operation is acceptable to the end user.

For a Fabry Perot type EEL, single mode operation can be achieved by employing an external cavity, located outside the EEL device. However, this method introduces optical losses in addition to significantly increasing the overall footprint of the device. DFB and DBR edge emitting lasers were therefore developed as a method for producing a single mode output beam from EEL devices. However, as the grating elements within these structures are known to introduce large optical losses, they act to reduce the maximum achievable output power of the edge emitting laser.

A common method for achieving high powers from EEL devices is to create a one-dimensional array of edge emitting lasers, known as a laser bar. The output from each element (edge-emitting laser) in the laser bar can be combined to create one output beam resulting in a higher combined output power. Furthermore, these laser bars may be arranged in the form of a vertical stack thus creating a two-dimensional array of edge emitters.

However, as each separate EEL is an individual element within the laser bar or the laser stack, they act independently of each other. Therefore, the resulting combined output beam, while higher in power, is incoherent and may contain a spread of output frequencies. However, the properties of having a coherent light source, such as uniformity and higher energy density, is desirable for a range of applications, including welding, cutting, high-speed information transfer, signal processing, and interferometry.

### SUMMARY OF INVENTION

It is therefore an object of an embodiment of the present invention to provide an alternative edge emitting laser system to those known in the art.

It is a further object of an embodiment of the present invention to provide an edge emitting laser system that exhibits improved operating parameters when compared with those known in the art. These improved operating parameters may include a coherent output field exhibiting increased output powers.

According to a first aspect of the invention there is provided an edge emitting laser (EEL) system comprising:
a first edge emitting laser (EEL), configured to generate laser radiation along a first longitudinal axis defined by an active layer of the first edge emitting laser, and one or more photonic crystal structures which are defined by a two-dimensional period array distributed in an array plane,
wherein the one or more photonic crystals are arranged to couple the generated laser radiation laterally across the first edge emitting laser.

The presence of the photonic crystal structure within the edge emitting laser (EEL) system results in the light scattering orthogonally within the photonic crystal to the direction of the output field generated along the longitudinal axis defined by the active layer of the first EEL. As a result of the photonic crystal structure, coherence is maintained across the width of the EEL system which causes the laser to generate an output field that maintains a single spatial and longitudinal mode of operation. As result, the area of the active layer of the first EEL can be increased to achieve a higher output power from the edge emitting laser system, and the presence of the photonic crystal structure within the EEL system prevents the output beam from exhibiting spatial or longitudinal mode hopping. In this way, the above EEL system produces a coherent beam, while obtaining higher output powers than for similar devices known in the art.

Preferably the edge emitting laser system may comprise a first and second confinement layer located on opposite sides of the active layer of the first edge emitting laser.

Preferably the edge emitting laser system may further comprise a first cladding layer located on the first confinement layer and a second cladding layer located on the second confinement layer.

The photonic crystal structure may be located within one or more of the layers of the first edge emitting laser; namely the active layer, the first confinement layer, the second confinement layer, the first cladding layer and or the second cladding layer.

Alternatively, the photonic crystal structure may be located external to the layers of the first edge emitting laser. In particular, the photonic crystal structure may be coupled to one or both end facets, wherein the end facets are the opposing longitudinal ends of the first edge emitting laser.

Preferably the edge emitting laser system further comprises a first and second electrical contact located on opposite external surfaces of the first edge emitting laser.

Preferably the width of the first edge emitting laser is greater than 10 μm. Alternatively, the width of the first edge emitting laser is greater than 20 μm or greater than 50 μm.

Preferably the edge emitting laser system further comprises a second edge emitting laser (EEL), configured to generate laser radiation along a second longitudinal axis defined by an active layer of the second edge emitting laser, the second longitudinal axis being parallel to the first longitudinal axis, wherein the one or more photonic crystal structures are arranged to couple the generated laser radiation between the first and second edge emitting lasers (EELs).

By providing a second edge emitting laser to the EEL system, the output power from first and second edge emitting lasers can be combined to create a higher combined output power for the EEL system. Furthermore, the presence of one or more photonic crystal structures to couple the generated laser radiation between the first and second edge emitting lasers results in coherent output fields from the first and second edge emitting lasers.

The one or more photonic crystal structures may be arranged to couple the generated laser radiation between the first and second edge emitting lasers by generating a coupling field that is coplanar with an array plane defined by the one or more photonic crystal structures.

The one or more photonic crystal structures may be arranged to couple the generated laser radiation between the first and second edge emitting lasers by generating a coupling field that is orthogonal with an array plane defined by the one or more photonic crystal structures.

Preferably the edge emitting laser system further comprises three or more edge emitting lasers, arranged to create a one- or two-dimensional array of edge emitting lasers, wherein the one or more photonic crystal structures are arranged to couple the generated laser radiation between the three or more edge emitting lasers.

By providing a plurality of edge emitting lasers within the edge emitting laser system, the output fields from each EEL can be combined to create a significantly higher combined output power for the EEL system. Due to the presence of the photonic crystal structure acting to couple the generated laser radiation between the plurality of EELs, coherent output fields are generated from each of the EELs. In this way an edge emitting laser system that produces a coherent output with even higher output powers may be realised. Such characteristics are desirable for many commercial laser applications.

Preferably the edge emitting laser system comprises a regular two-dimensional array wherein an edge emitting laser is located at each site of the array.

Alternatively, the edge emitting laser system is an irregular two-dimensional array. The irregular array may comprise a regular two-dimensional array where there is no edge emitting laser located at one or more of the array sites.

Optionally one or more wavelength-selective reflectors may be placed outside the one or more photonic crystal structures. The presence of the one or more reflectors act to reduce the effects of undesired light leakage from the one or more photonic crystal structures.

According to a second aspect of the invention there is provided a method of manufacturing an edge emitting laser system the method comprising:
providing a first edge emitting laser;
configuring the first edge emitting laser to generate laser radiation along a first longitudinal axis defined by an active layer of the first edge emitting laser;
providing one or more photonic crystal structures which are defined by a two-dimensional period array distributed in an array plane and
arranging the one or more photonic crystal structures to couple the generated laser radiation laterally across the first edge emitting laser.

Preferably the method of manufacturing an edge emitting laser system further comprises providing first and second confinement layers on opposite sides of the active layer of the first edge emitting laser.

Preferably the method of manufacturing an edge emitting laser system further comprises providing a first cladding layer on the first confinement layer and providing a second cladding layer on the second confinement layer.

Preferably the method of manufacturing an edge emitting laser system further comprises arranging the photonic crystal structure so that it is located within one or more of the layers of the first edge emitting laser; namely the active layer, the first confinement layer, the second confinement layer, the first cladding layer and or the second cladding layer.

Alternatively, the method of manufacturing an edge emitting laser system comprises arranging the photonic crystal structure so that it is located external to the layers of the first edge emitting laser. In particular, the method may comprise coupling the photonic crystal structure to one or both end facets, wherein the end facets are the opposing longitudinal ends of the first edge emitting laser.

Preferably the method of manufacturing an edge emitting laser system further comprises providing a first and second electrical contact on opposite external surfaces of the first edge emitting laser.

Preferably the method of manufacturing an edge emitting laser system further comprises producing a width for the first edge emitting laser that is greater than 10 μm. Alternatively, the method of manufacturing an edge emitting laser system further comprises producing a width for the first edge emitting laser that is greater than 20 μm or greater than 50 μm.

Preferably the method of manufacturing an edge emitting laser system further comprises:
providing a second edge emitting laser;
configuring the second edge emitting laser to generate laser radiation along a second longitudinal axis defined by an active layer of the second edge emitting laser,
arranging the second longitudinal axis to be parallel to the first longitudinal axis and
arranging the one or more photonic crystal structures to couple the generated laser radiation between the first and second edge emitting lasers.

The method of manufacturing an edge emitting laser system further comprises arranging the one or more photonic crystal structures to couple the generated laser radiation between the first and second edge emitting lasers by generating a coupling field that is coplanar with an array plane defined by the one or more photonic crystal structures.

The method of manufacturing an edge emitting laser system further comprises arranging the one or more photonic crystal structures to couple the generated laser radiation between the first and second edge emitting lasers by generating a coupling field that is orthogonal with an array plane defined by the one or more photonic crystal structures.

Preferably the method of manufacturing an edge emitting laser system can further comprise:
providing three or more edge emitting lasers,
arranging the three or more edge emitting lasers to create a one- or two-dimensional array of edge emitting lasers, and
arranging the one or more photonic crystal structures to couple the generated laser radiation between the three or more edge emitting lasers.

The method of manufacturing an edge emitting laser system further comprises providing a regular two-dimensional array of edge emitting lasers and arranging the plurality of edge emitting lasers so that an edge emitting laser is located at each site of the array.

Alternatively, the method of manufacturing the edge emitting laser system comprises providing an irregular two-dimensional array of edge emitting lasers. The irregular array may be provided by arranging the plurality of edge emitting lasers so that there is no edge emitting laser located at one or more of the array sites of a regular array.

Optionally the method of manufacturing the edge emitting laser system comprises providing one or more wavelength-selective reflectors outside the one or more photonic crystal structures.

Embodiments of the second aspect of the present invention may comprise features to implement the preferred or optional features of the first aspects of the present invention or vice versa.

### BRIEF DESCRIPTION OF DRAWINGS

There will now be described, by way of example only, various embodiments of the invention with reference to the drawings, of which:

FIG. 1 presents a cross sectional view of an edge emitting laser as is known in the art;

FIG. 2 presents a cross sectional view of an edge emitting laser system in accordance with an embodiment of the present invention;

FIG. 3 presents experimental results showing output spectra from the edge emitting laser of FIG. 1 and the edge emitting laser system of FIG. 2;

FIG. 4 presents a cross sectional view of an edge emitting laser system in accordance with an alternative embodiment of the present invention;

FIG. 5 presents a cross sectional view of an edge emitting laser system in accordance with an alternative embodiment of the present invention;

FIG. 6 presents a cross sectional view of an edge emitting laser system in accordance with an alternative embodiment of the present invention;

FIG. 7 presents a cross sectional view of an edge emitting laser system in accordance with an alternative embodiment of the present invention;

FIG. 8 presents a cross sectional view of an edge emitting laser system in accordance with an alternative embodiment of the present invention;

FIG. 9 presents a cross sectional view of an edge emitting laser system in accordance with an alternative embodiment of the present invention;

FIG. 10 presents an edge emitting laser system in accordance with an alternative embodiment of the present invention;

FIG. 11 presents an edge emitting laser system in accordance with an alternative embodiment of the present invention;

FIG. 12 presents an edge emitting laser system in accordance with an alternative embodiment of the present invention; and

FIG. 13 presents an edge emitting laser system in accordance with an alternative embodiment of the present invention.

In the description which follows, like parts are marked throughout the specification and drawings with the same reference numerals. The drawings are not necessarily to scale and the proportions of certain parts have been exaggerated to better illustrate details and features of embodiments of the invention.

### DETAILED DESCRIPTION

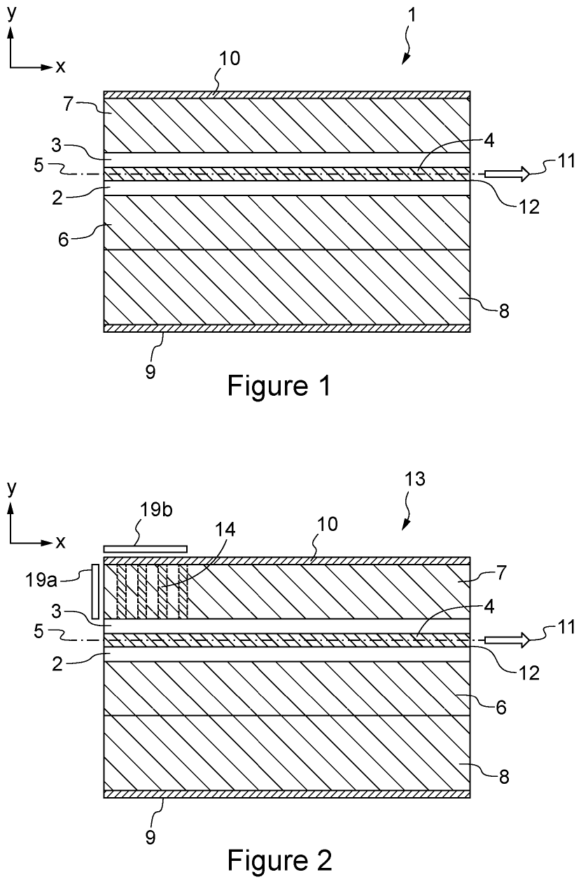

FIG. 1 presents a cross sectional view of a standard edge emitting laser (EEL), as generally depicted by reference numeral 1, as is known in the art. An x-y axis is included for reference, where the height of the EEL 1 is along the y axis and the length of the EEL 1 is along the x axis.

The EEL 1 of FIG. 1 can be seen to comprise a number of layers.

Firstly, within the EEL 1 there is a waveguide region which comprises first 2 and second 3 confinement layers, between which is located an active layer 4 that generates laser radiation in a direction substantially parallel to a longitudinal axis 5 of the EEL 1 when a drive current is passed through the EEL 1.

The active layer 4 may comprise many different structures, as known to those skilled in the art. The active layer 4 of the EEL 1 can be, in particular, a single or multiple quantum well structure. In general, the active layer 4 will comprise multiple quantum wells equally spaced between half-wave structures that allow the active layer 4 to be electrically pumped by an input drive current.

The waveguide region is arranged between a first cladding layer 6 and a second cladding layer 7. One of the cladding layers 6 or 7 comprises an n-type semiconductor material and the other cladding layer 6 or 7 comprises a p-type semiconductor material. The edge emitting laser 1 additionally comprises a substrate layer 8, and the other layers 2, 3, 4, 6 and 7 are formed or grown on the substrate layer 8.

Electrical contact is made with the edge emitting laser 1 by employing a first 9 and second 10 electrical contact layer. The electrical contact layers 9 and 10 are located on opposite external surfaces of the EEL 1.

As a result of the above structure, when an electrical current is provided between the first 9 and second 10 electrical contacts, the EEL 1 begins to lase and an output field 11 is emitted from the output surface 12 of the EEL 1 in a direction substantially parallel to the x-axis.

One or more intermediate layers may be arranged between the substrate layer 8 of the EEL 1 and the first cladding layer 6, as required. Furthermore, one or more intermediate layers can also be arranged between the second cladding layer 7 and the second electrical contact layer 10.

The first 6 and second 7 cladding layers have a lower refractive index than the first 2 and second 3 confinement layers, which allows for the propagating laser radiation to be guided within the waveguide region.

The output field 11 generated by the above-described EEL 1 typically has multiple modes or wavelengths. As described previously, most known methods to provide single mode operation result in a lower output power for the EEL 1.

An edge emitting laser system 13 in accordance with an embodiment of the present invention, and its method of production, will now be described with reference to FIG. 2.

In particular, FIG. 2 presents a cross sectional view of the edge emitting laser system 13 in accordance with an embodiment of the present invention.

The edge emitting laser system 13 of FIG. 2 comprises a similar structure to the EEL 1 presented within FIG. 1. However, unlike the EEL 1 of FIG. 1, the EEL system 13 incorporates a photonic crystal structure 14 within the second cladding layer 7 of the EEL system 13.

The photonic crystal structure 14 is a material, such as a semiconductor material, comprising a two-dimensional period array of voids or all-semiconductor atoms distributed in an array plane. The array of voids or atoms usually form a periodic lattice structure, where the refractive index of the void or atoms is different to the photonic crystal material.

The lattice structure of the photonic crystal structure 14 causes Bragg diffraction within the photonic crystal, which in turn causes light to resonate at a particular wavelength determined by the periodicity, or lattice constant, of the photonic crystal structure 14.

The voids or atoms that are formed in the photonic crystal structure 14 are usually periodic in nature and may be formed in different shapes or geometries. In the presently described embodiment, the atoms comprise circular atoms arranged within a square lattice having a lattice constant of 305 nm. It will be appreciated by the skilled reader that, in alternative embodiments, the voids or atoms of the photonic crystal structure may comprise different shapes or structures and different lattice constants. For example, the atoms May comprise different regular or irregular geometric shapes (e.g., triangular, oval, diamond, square or chevron shapes) and the lattice may comprise alternative regular or irregular lattice structures (e.g., triangular, hexagonal or Kagome) having different lattice constants.

The output field 11 from the EEL system 13 is emitted from the output surface 12 located at the edge of the EEL system 13, where the generated radiation travels along in a direction substantially parallel to the longitudinal axis 5 of the EEL system 13. However, within the photonic crystal structure 14 the generated laser radiation is scattered orthogonally to the longitudinal axis 5. This orthogonal scattering is both coplanar with, and orthogonal to, the array plane of the photonic crystal structure 14. Therefore, as a result of the presence of the photonic crystal structure 14 within the first cladding layer 6 of the EEL system 13, coherence is maintained across the width of the EEL system 13. This results in the EEL system 13 generating an output field 11 that maintains a single spatial and longitudinal mode of operation, thus creating a coherent and high power output field 11.

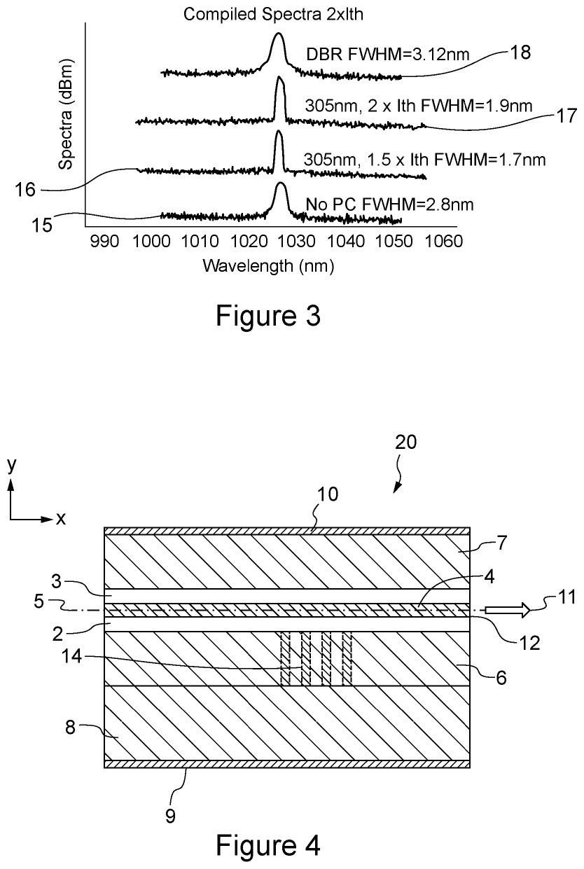

Evidence of the single spatial and longitudinal mode of operation of the EEL system 13 is presented in FIG. 3 which presents output spectra 15, 16 and 17 generated from the output fields 11 of the EEL 1 of FIG. 1 and the EEL system 13 of FIG. 2. In particular, output spectrum 15 was obtained from the EEL 1 of FIG. 1 while operating with a drive current at twice the threshold current of the device. In a similar manner, output spectra 16 and 17 were obtained from the EEL system 13 of FIG. 2 while operating with a drive current at 1.5 times and twice, respectively, the threshold current of the device. For comparison purposes, a further output spectrum 18 was generated from the EEL 1 of FIG. 1 where a DBR was located external to, but optically coupled with, the active layer 4 of the device.

As can be clearly seen, output spectra 16 and 17 obtained from the EEL system 13 of FIG. 2 exhibit respective linewidths of 1.7 nm and 1.9 nm. These are both significantly narrower than the linewidth of the output spectrum 15 obtained from the EEL 1 of FIG. 1 which measures around 2.8 nm. This is indicative of the fact that the EEL system 13 is generating an output field 11 that comprises a single spatial and longitudinal mode. Evidence that it is the presence of the photonic crystal structure 14 that results in the EEL system 13 operating with a single spatial and longitudinal mode is provided with reference to output spectrum 18. It can be seen that, unlike the case when a photonic crystal structure 14 is incorporated within the EEL system 13, optical feedback generated by the presence of the DBR located external to, but optically coupled with, to the active layer 4 of the EEL 1 actually results in an increase of the linewidth of the generated output field 11 to 3.12 nm.

One particular advantage of the described EEL system 13 is that the width of the EEL system 13 can be increased to dimensions on the order of 10's of μm, while still maintaining a single spatial and longitudinal mode of operation. For similar EELs 1 known in the art, increasing the width of the EEL 1 to dimensions greater than 10 μm would result in spatial multimode operation. However, the presence of the photonic crystal structure 14 within the EEL system 13 allows for the EEL system 13 to continue to maintain single mode operation as the width of the EEL system 13 is increased. By increasing the width of the EEL system 13 the power of the output field 11 of the EEL system 13 can also be significantly increased.

The EEL system 13 of FIG. 2 may further comprise one or more wavelength selective reflectors 19 located outside of the semiconductor structure of the EEL system 13. The wavelength selective reflectors 19a, 19b are designed to reflect the light at a selected wavelength i.e. the wavelength of the output field 11. The location of the one or more wavelength selective reflectors 19a, 19b are chosen to reflect the orthogonally scattered light generated by the photonic crystal structure 14 back into the active layer 4 of the EEL system 13 thus reducing the effect of light leakage from the EEL system 13 and so increasing the power of the output field 11 of the EEL system 13.

An EEL system 20 in accordance with an alternative embodiment of the present invention is presented in FIG. 4. The EEL system 20 of FIG. 4 is similar to that shown in FIG. 2, however in FIG. 4 the photonic crystal structure 14 is provided within a different layer of the EEL system 20, namely the first cladding layer 6.

It will be appreciated by the skilled reader that the photonic crystal structure 14 may be provided within any layer of the EEL system, and that there is no requirement for the photonic crystal structure 14 to be within the second 7 or first 6 cladding layers, as shown in FIGS. 2 and 4, respectively. The photonic crystal structure 14 may be provided at any location within the EEL system that allows it to generate orthogonal scattering fields that act to maintain coherence across the EEL system. Additionally, if one or more further intermediate layers are arranged between the first cladding layer 6 and the substrate layer 8 of the EEL system or the second cladding layer 7 and the second electrical contact layer 10, the photonic crystal structure 14 could also be alternatively placed within these intermediate layers.

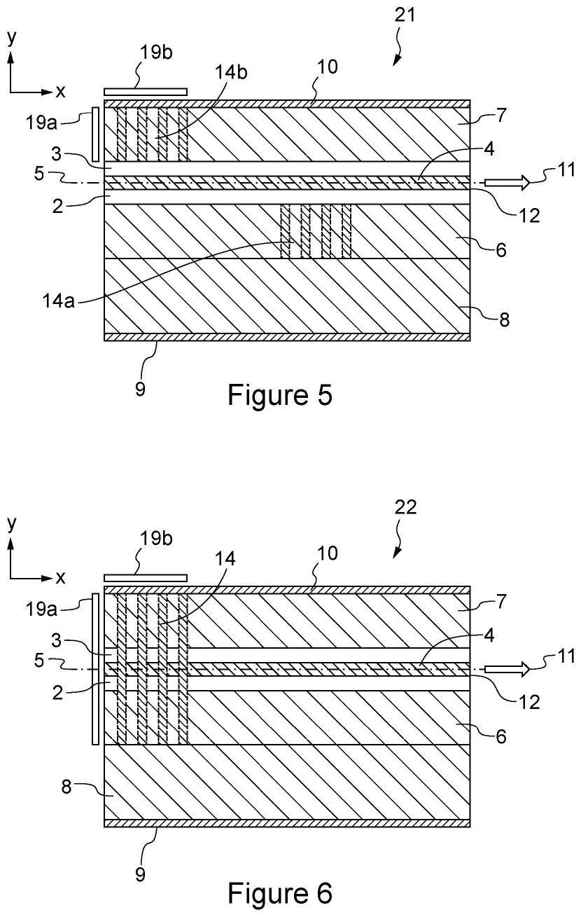

By way of example, a further alternative embodiment of an EEL system 21 is presented in FIG. 5. In FIG. 5, the EEL system 21 comprises a similar structure to the EEL systems and 20 presented within FIGS. 2 and 4, respectively, however in this embodiment both a first 14a and a second 14b photonic crystal structure are present. The first photonic crystal structure 14a is provided within the first cladding layer 6 of the EEL system 21 and the second photonic crystal structure 14b is provided within the second cladding layer 7 of the EEL system 21.

As will be appreciated by the skilled reader the number of photonic crystal structures 14 within the EEL system is not limited to two, and there could be further photonic crystal structures 14 arranged within the EEL system as desired. Furthermore, each photonic crystal structure 14 may be arranged within different layers, as illustrated in FIG. 5, or alternatively the photonic crystal structures 14 may be arranged within the same layer of the EEL system.

A further alternative embodiment of an EEL system 22 is presented in FIG. 6, whereby the photonic crystal structure 14 is present within all of the layers 2, 3, 4, 6 and 7 of the EEL system 22. In particular the photonic crystal structure 14 extends from the first cladding layer 6 to the second cladding layer 7, passing through each of the first confinement layer 2, the active layer 4 and the second confinement layer 3.

It will be appreciated by the skilled reader that the photonic crystal structure 14 could alternatively be present within fewer layers than is shown within FIG. 6, or within any further intermediate layers that may be added to the EEL system 22. For example, the photonic crystal structure 14 could instead extend from the first cladding layer 6 to the active layer 4 (i.e., in this case would not extend into the second confinement layer 3 or the second cladding layer 7).

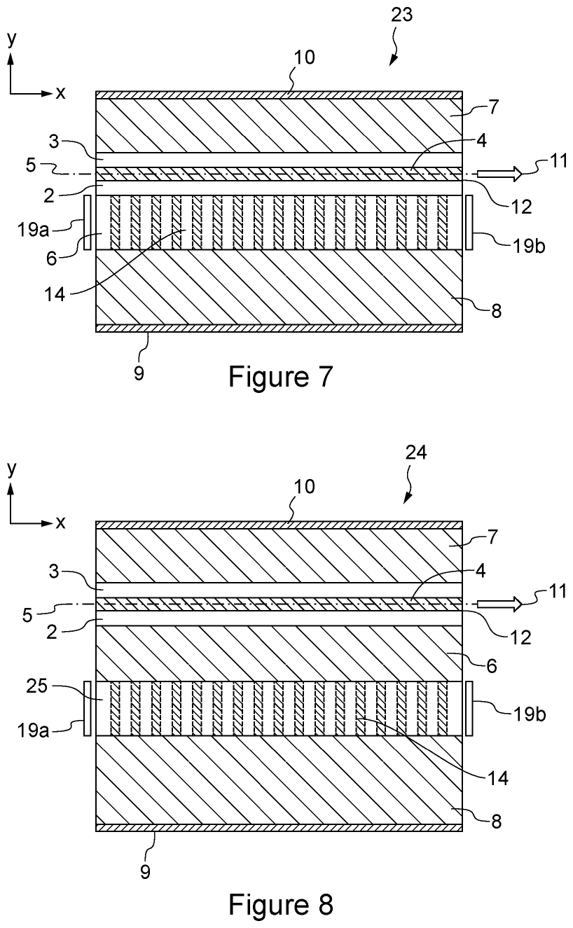

A further alternative embodiment of an EEL system 23 is presented in FIG. 7 where the photonic crystal structure 14 within the EEL system 23 is provided as a photonic crystal layer. In the EEL system 23 of FIG. 7 the photonic crystal structure 14 is located within the first cladding layer 6 of the EEL system 23. However, it will again be appreciated by the skilled reader that such a photonic crystal layer could be situated within any of the layers of the EEL system 23.

A further alternative embodiment of an EEL system 24 is presented in FIG. 8, where, similar to FIG. 7, the photonic crystal structure 14 is again provided as a photonic crystal layer. However, the photonic crystal layer in the EEL system 24 of FIG. 8 is an additional intermediate layer 25 provided within the EEL system 24, and the photonic crystal structure 14 is not present within the other layers 2, 3, 4, 7 and 8.

Note that there may be more than one photonic crystal layer arranged within the EEL system. Any further photonic crystal layers may be arranged either as an additional separate intermediate layer, or as a photonic crystal layer within one of the existing layers 2, 3, 4, 6 and 7 of the EEL system.

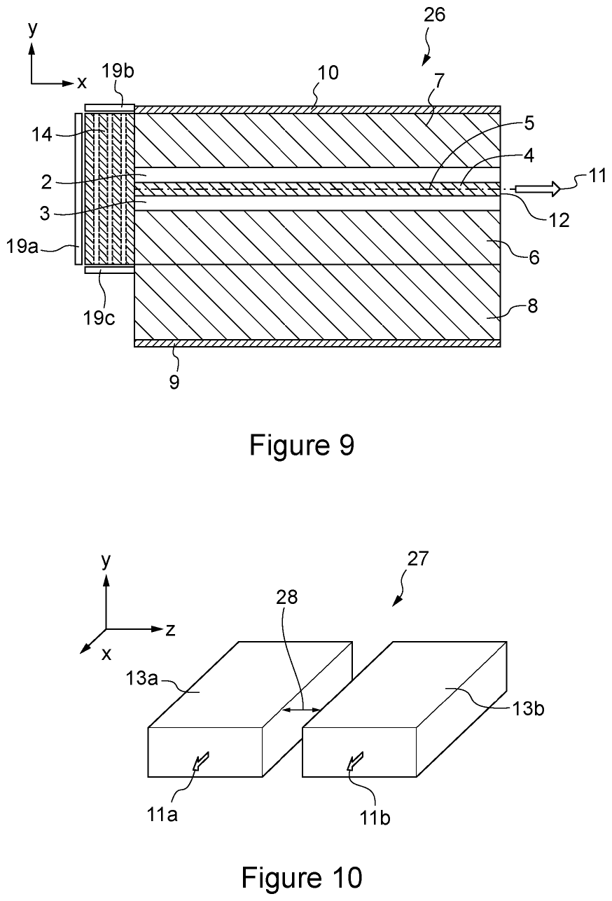

A further alternative embodiment of an EEL system 26 is presented in FIG. 9. In the EEL system 26 of FIG. 9, the photonic crystal structure 14 is located externally to the other layers of the EEL system 26. In particular, the photonic crystal structure 14 is coupled to an end facet, i.e., a longitudinal end of the EEL system 26. It will be appreciated by the skilled reader that more than one photonic crystal structure 14 may be located external to the EEL system. For example, there may two photonic crystal structures 14 coupled to each of the opposing longitudinal ends of the EEL system 26. Furthermore, the height of the photonic crystal structure 14 may also be increased or decreased (i.e., along the y axis) compared to that depicted in FIG. 9.

It will further be appreciated by the skilled reader that the EEL system 26 may be combined with any of the embodiments illustrated in FIGS. 2 and 4 to 8. In this way an EEL system may be provided that contains photonic crystals structures 14 both external to the other layers of the EEL system and or within the other layers of the EEL system.

A further alternative embodiment of an EEL 27 is presented in FIG. 10. Here an x-y-z axis is provided for ease of reference, where the height of the EEL system 27 is along the y axis, the length along the x axis and the width along the z axis.

In particular, FIG. 10 presents an EEL system 27 that effectively comprises two EEL systems 13a and 13b of the type shown in FIG. 2. The EEL systems 13a and 13b are placed side by side, along the z axis, and thus the EEL system 27 provides two output fields 11a and 11b. The first 11a and second 11b output fields can be combined, providing a higher combined output power for the EEL system 27, that is around twice the output power of a single EEL 13.

The photonic crystal structures 14 provided within the EEL system 27 scatters the light and creates a first coupling field 28 between the first 13a and second 13b EEL systems, where the first coupling field 28 propagates along the z axis. In particular, the first coupling field is coplanar with the array plane defined by the photonic crystal structures 14. As a result, the first coupling field 28 acts to maintain coherence within the EEL system 27, and so the two output fields 11a and 11b are coherent with each other.

Therefore, the described EEL system 27 provides a coherent output combined with a higher output power than for the previously described embodiments.

Note that rather than having two separate photonic crystal structures 14 within each of the first 13a and second 13b EEL systems, a single photonic crystal structure 14 could instead connect the first 13a and second 13b EEL systems along their width (z axis). As for the previous embodiments, it will be appreciated by the skilled reader that the EEL system 27 could also contain further photonic crystal structures 14 which may be provided within any layer, or external to the layers, of either the first 13a and second 13b EEL systems.

Furthermore, additional EEL systems 13 of the type shown within FIG. 2 could also be added to the EEL system 27, i.e., forming a one-dimensional array of side-by-side elements, where the photonic crystal structure(s) 14 creates a coupling field 28 between all the individual EEL systems 13 of the EEL system 27. Such an array of EEL elements is commonly known as a laser bar, where the array is integrated into a single chip and the light output from each EEL element within the laser bar can be combined to produce significantly higher output powers. However, unlike the laser bars of the prior art, the output fields 11 of each EEL 13 of the EEL system 27 are coherent with each other.

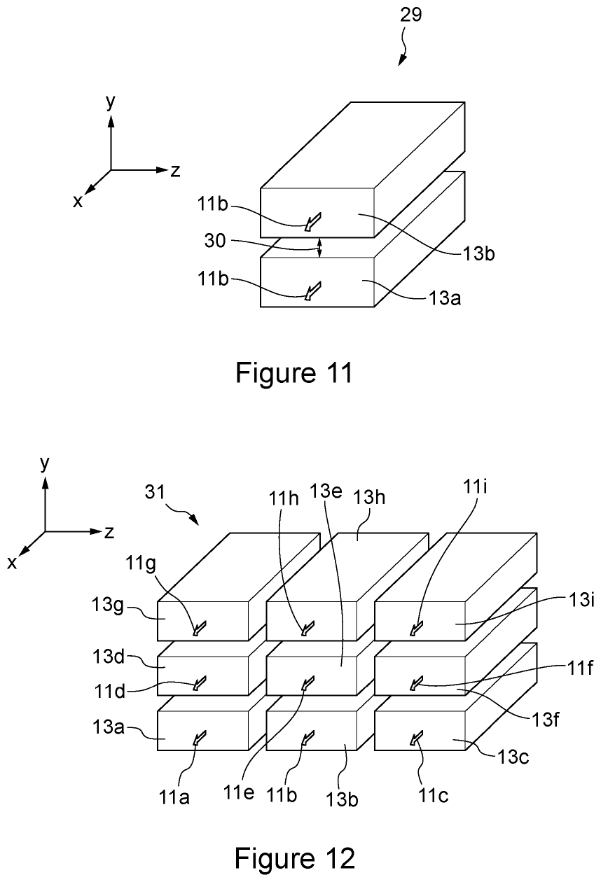

A further alternative embodiment of an EEL system 29 is presented in FIG. 11. The EEL system 29 is similar to that of FIG. 10 and comprises a first 13a and a second 13b EEL systems. However, for the EEL system 29 of FIG. 11, the second EEL system 13b is placed on top of the first EEL 13a to form a stack along the y axis.

As a result, a second coupling field 30 is provided by the photonic crystal structure(s) 14, whereby the second coupling field 30 between the EEL systems 13a and 13b propagates along the y axis, orthogonal to the photonic crystal structure 14.

It will again be appreciated by the skilled reader that further EEL systems 13 of the type shown in FIG. 2 could be added to the EEL system 29 of FIG. 11 to form a single stack, where the second coupling field 30 generated by the photonic crystal structure(s) 14 couples all the individual EEL systems 13 within the EEL system 29.

A further alternative embodiment of an EEL system 31 is presented in FIG. 12, showing a combination of the EEL systems 27 and 29 as presented in FIGS. 10 and 11, respectively. By combining an array of both side by side and stacked EEL systems a regular two-dimensional array of three-by-three elements is created.

The photonic crystal structures 14 are arranged within the EEL system 31 to create both a first 28 and second 30 coupling field between all the EEL systems 13a to 13i within the EEL system 31. This results in multiple output fields 11a to 11i which are coherent with each other, and which can be combined to produce a single, high power, output beam. It will be appreciated by the skilled reader that the EEL system 31 may comprise less or more EEL elements 13 than are shown in FIG. 12, to either reduce or increase the size of the two-dimensional array and hence the number of output fields 11.

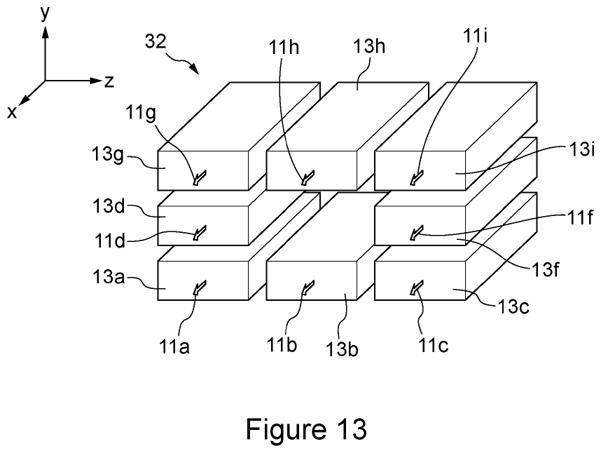

A further alternative embodiment of an EEL 32 is presented in FIG. 13, which again combines the EEL systems 27 and 29 as presented in FIGS. 10 and 11, respectively. However, here the combination of side by side and stacked elements is used to construct an irregular two-dimensional array. In particular, in FIG. 13 there is no EEL element present at the centre array site (i.e., 13e in FIG. 12) of the EEL system 32.

It will be appreciated by the skilled reader that the array of EEL systems 13a to 13i within the EEL system 32 can be assembled in any desired geometry. For example, an EEL element 13 could be removed from a different array site than shown for FIG. 13. Furthermore, an EEL element 13 could also be removed from more than one array site. As for the previous embodiment, the EEL system 32 can comprise fewer EEL elements 13 than those shown in FIG. 13 or alternatively further elements can be added to the EEL system 32 to create a larger irregular two-dimensional array, with a higher output power.

Each of the embodiments of FIGS. 10 to 13 discuss using an EEL system 13 of the type presented in FIG. 2. However, as will be appreciated by the skilled reader, the EEL elements could instead be any of the EEL systems 13, 20, 21, 22, 23, 24 and 26 as described with reference to FIGS. 2 and 4 to 9, or any combination thereof.

In summary, the present invention provides an alternative EEL device to those known in the art, with improved operating parameters. In particular, the present invention provides an EEL system which is fabricated in a manner that results in high output powers, while maintaining a single spatial and longitudinal mode of operation, resulting in a high-power coherent output beam. The disclosed EEL systems increase the output power without introducing significant optical losses, or a loss of coherence due to the device exhibiting the detrimental effects of spatial or longitudinal mode hopping. Furthermore, the improved operating parameters of the EEL system can be achieved without increasing the overall footprint of the device.

An edge emitting laser (EEL) system and a method for manufacturing is disclosed. The EEL system comprises an EEL structure, configured to generate laser radiation along a first longitudinal axis defined by an active layer of the EEL system. The EEL system further comprises a photonic crystal structure. The photonic crystal structure is defined by a two-dimensional period array distributed in an array plane and is arranged to couple the generated laser radiation laterally across the EEL system. The presence of the photonic crystal structure within the EEL system results in light scattering orthogonally within the photonic crystal to the output field generated by the EEL system. The described EEL system allows for the area of the EEL system to be increased while maintaining a single spatial and longitudinal mode of operation, resulting in a coherent beam with a high output power.

Throughout the specification, unless the context demands otherwise, the term “comprise” or “include”, or variations such as “comprises” or “comprising”, “includes” or “including” will be understood to imply the inclusion of a stated integer or group of integers, but not the exclusion of any other integer or group of integers.

Furthermore, reference to any prior art in the description should not be taken as an indication that the prior art forms part of the common general knowledge.

The foregoing description of the invention has been presented for purposes of illustration and description and is not intended to be exhaustive or to limit the invention to the precise form disclosed. The described embodiments were chosen and described in order to best explain the principles of the invention and its practical application to thereby enable others skilled in the art to best utilise the invention in various embodiments and with various modifications as are suited to the particular use contemplated. Therefore, further modifications or improvements may be incorporated without departing from the scope of the invention as defined by the appended claims.

1. An edge emitting laser system comprising:
a first edge emitting laser, configured to generate laser radiation along a first longitudinal axis defined by an active layer of the first edge emitting laser, and to provide a first output field,
one or more photonic crystal structures which are defined by a two-dimensional period array distributed in an array plane,
wherein the one or more photonic crystals are arranged to couple the generated laser radiation laterally across the first edge emitting laser,
a second edge emitting laser configured to generate laser radiation along a second longitudinal axis defined by an active layer of the second edge emitting laser, and to provide a second output field, the second longitudinal axis being parallel to the first longitudinal axis,
wherein the one or more photonic crystal structures are arranged to couple the generated laser radiation between the first and second edge emitting lasers.

2. An edge emitting laser system as claimed in claim 1, wherein the first edge emitting laser further comprises a first and second confinement layer located on opposite sides of the active layer.

3. An edge emitting laser system as claimed in claim 2, wherein the first edge emitting laser further comprises a first cladding layer located on the first confinement layer and a second cladding layer located on the second confinement layer.

4. An edge emitting laser system as claimed in claim 1, wherein the one or more photonic crystal structures may be located within one or more of the layers of the first edge emitting laser; namely the active layer, the first confinement layer, the second confinement layer, the first cladding layer and or the second cladding layer.

5. An edge emitting laser system as claimed in claim 1, wherein the one or more photonic crystal structures may be located external to the layers of the first edge emitting laser.

6. An edge emitting laser system as claimed in claim 5, wherein the one or more photonic crystal structures may be coupled to one or both end facets of the first edge emitting laser, wherein the end facets are the opposing longitudinal ends of the first edge emitting laser.

7. An edge emitting laser system as claimed in claim 1, wherein the width of the first edge emitting laser is greater than 10 μm, or greater than 20 μm or greater than 50 μm.

8. (canceled)

9. An edge emitting laser system as claimed in claim 1, wherein one or more photonic crystal structures may be arranged to couple the generated laser radiation between the first and second edge emitting lasers by generating a coupling field that is coplanar with an array plane defined by the one or more photonic crystal structures.

10. An edge emitting laser system as claimed in claim 1, wherein one or more photonic crystal structures may be arranged to couple the generated laser radiation between the first and second edge emitting lasers by generating a coupling field that is orthogonal with an array plane defined by the one or more photonic crystal structures.

11. An edge emitting laser system as claimed in claim 1, wherein the edge emitting laser system further comprises three or more edge emitting lasers, arranged to create a one- or two-dimensional array of edge emitting lasers, wherein the one or more photonic crystal structures are arranged to couple the generated laser radiation between the three or more edge emitting lasers.

12. An edge emitting laser system as claimed in claim 11, wherein the edge emitting laser system comprises a regular two-dimensional array wherein an edge emitting laser is located at each site of the array.

13. An edge emitting laser system as claimed in claim 11, wherein the edge emitting laser system comprises an irregular two-dimensional array, wherein the irregular array comprises a regular two-dimensional array where there is no edge emitting laser located at one or more of the array sites.

14. An edge emitting laser system as claimed in claim 1, wherein one or more wavelength-selective reflectors may be placed outside the one or more photonic crystal structures.

15. A method of manufacturing an edge emitting laser system the method comprising:
providing a first edge emitting laser;
configuring the first edge emitting laser to generate laser radiation along a first longitudinal axis defined by an active layer of the first edge emitting laser, and to provide a first output field;
providing one or more photonic crystal structures which are defined by a two-dimensional period array distributed in an array plane;
arranging the one or more photonic crystal structures to couple the generated laser radiation laterally across the first edge emitting laser;
providing a second edge emitting laser;
configuring the second edge emitting laser to generate laser radiation along a second longitudinal axis defined by an active layer of the second edge emitting laser, and to provide a second output field;
arranging the second longitudinal axis to be parallel to the first longitudinal axis; and
arranging the one or more photonic crystal structures to couple the generated laser radiation between the first and second edge emitting lasers.

16. A method of manufacturing an edge emitting laser system as claimed in claim 15, the method further comprising providing first and second confinement layers on opposite sides of the active layer of the first edge emitting laser.

17. A method of manufacturing an edge emitting laser system as claimed in claim 15, the method further comprising providing a first cladding layer on the first confinement layer and providing a second cladding layer on the second confinement layer.

18. A method of manufacturing an edge emitting laser system as claimed in claim 15, the method further comprising arranging the one or more photonic crystal structures so that it is located within one or more of the layers of the first edge emitting laser; namely the active layer, the first confinement layer, the second confinement layer, the first cladding layer and or the second cladding layer.

19. A method of manufacturing an edge emitting laser system as claimed in claim 15, the method further comprising arranging the one or more photonic crystal structures so that it is located external to the layers of the first edge emitting laser.

20. (canceled)

21. A method of manufacturing an edge emitting laser system as claimed in claim 15, the method further comprising arranging the one or more photonic crystal structures to couple the generated laser radiation between the first and second edge emitting lasers by generating a coupling field that is coplanar with an array plane defined by the one or more photonic crystal structures.

22. A method of manufacturing an edge emitting laser system as claimed in claim 15, the method further comprising arranging the one or more photonic crystal structures to couple the generated laser radiation between the first and second edge emitting lasers by generating a coupling field that is orthogonal with an array plane defined by the one or more photonic crystal structures.

23. A method of manufacturing an edge emitting laser system as claimed in claim 15, the method comprising:
providing three or more edge emitting lasers,
arranging the three or more edge emitting lasers to create a one- or two-dimensional array of edge emitting lasers, and
arranging the one or more photonic crystal structures to couple the generated laser radiation between the three or more edge emitting lasers.

24. A method of manufacturing an edge emitting laser system as claimed in claim 23, the method comprising providing a regular two-dimensional array of edge emitting lasers and arranging the plurality of edge emitting lasers so that an edge emitting laser is located at each site of the array.

25. A method of manufacturing an edge emitting laser system as claimed in claim 23, the method comprising providing an irregular two-dimensional array of edge emitting lasers wherein the irregular array comprises a regular two-dimensional array where there is no edge emitting laser located at one or more of the array sites.
